(19) United States
(12) Patent Application Publication
(10) Pub. No.: US 2018/0190511 A1
(43) Pub. Date: Jul. 5, 2018

(54) METHOD FOR MANUFACTURING A COVER FOR AN ELECTRONIC PACKAGE AND ELECTRONIC PACKAGE COMPRISING A COVER

(71) Applicant: STMicroelectronics (Grenoble 2) SAS, Grenoble (FR)

(72) Inventors: Alexandre Mas, Saint Egreve (FR); Benoit Besancon, Villard Bonnot (FR); Karine Saxod, Les Marches (FR)

(73) Assignee: STMicroelectronics (Grenoble 2) SAS, Grenoble (FR)

(21) Appl. No.: 15/685,285

(22) Filed: Aug. 24, 2017

(30) Foreign Application Priority Data
Jan. 3, 2017 (FR) 1750050

(51) Int. Cl. H01L 21/56; H01L 23/28; H01L 23/02

(52) U.S. Cl. CPC H01L 21/565; H01L 23/02; H01L 23/28

(57) ABSTRACT

A method for manufacturing a cover for an electronic package includes placing an electrically conductive insert (including an electrical contact surface) inside a cavity of a mold in a position such that the electrical contact surface is in contact with a face of the cavity of the mold. A coating material is injected into said cavity and set so as to produce a substrate that is overmolded around the insert and forms the cover where the electrical contact surface of the overmolded substrate is not covered by the coating material. An electronic package is then formed from a chip mounted on a carrier substrate that is covered by the cover. The electrical contact surface is located above and electrically connected to an electrical connection pad of either the chip or the carrier substrate.

### PRIORITY CLAIM

This application claims the priority benefit of French Application for Patent No. 1750050, filed on Jan. 3, 2017, the disclosure of which is hereby incorporated by reference in its entirety.

### TECHNICAL FIELD

The present invention relates to the field of electronic packages, in particular those which comprise electronic chips including light radiation emitters and/or light radiation sensors.

### BACKGROUND

It is known practice to produce electronic packages which comprise electronic chips mounted on carrier substrates and which comprise encapsulation covers for the chips, which covers are fixed to the carrier substrates. For specific needs, in particular optical, heat dissipation, electrical or electromagnetic needs, the encapsulation covers are provided with members suited to these needs. These members are transferred onto the covers after the latter have been mounted on the carrier substrates and are fixed to the covers by way of layers or beads of adhesive.

### SUMMARY

According to one embodiment, a method is proposed for manufacturing at least one cover for an electronic package, which comprises the following steps: placing at least one insert made of an electrically conductive material, comprising at least one electrical contact, inside a cavity of a mold, in a position such that said electrical contact makes contact with a face of said cavity of the mold; injecting a coating material into said cavity; and setting the coating material in order to obtain a substrate that is at least partly overmolded around said insert, so as to produce at least one cover comprising at least a portion of said overmolded substrate and at least one insert of which at least part of said electrical contact is not covered by the coating material.

The method may comprise a later step of cutting through said overmolded substrate at a distance from said electrical insert.

Said electrical contact of said insert may be located on the side of a mounting face of said cover.

Said insert may comprise a substrate.

Said insert may comprise a wire element.

The mold may comprise a layer made of a compressible material at least partly forming the face of said cavity with which said electrical contact makes contact.

Said insert may have a part that makes contact with a face of the mold opposite said face with which said electrical contact makes contact.

Said opposite faces of the mold may be parallel.

A face of the cavity of the mold may comprise at least one zone surrounded by at least one protruding groove, such that said substrate of the obtained cover is provided with at least one protruding rib corresponding to said groove of the mold.

Said electrical contact of said electrical insert may make contact with said zone.

Said electrical contact of said electrical insert may make contact with the bottom of said groove.

The method may comprise a later cutting step carried out through said protruding rib.

A method is also proposed for manufacturing an electronic package, which comprises the following steps: obtaining an encapsulation cover manufactured according to the above method; obtaining a carrier substrate provided with an electronic chip on top of a mounting face; and mounting the encapsulation cover above said mounting face of said carrier substrate, such that the encapsulation cover extends above said chip, said electrical contact of said insert is located above an electrical connection pad of said contact substrate and/or above an electrical connection pad of said chip, and said electrical contact of said insert and said electrical connection pad are electrically connected.

The method may comprise the following step: electrically connecting said electrical contact of said insert and said electrical connection pad by interposing an electrically conductive material therebetween.

An electronic package is also proposed which comprises: a carrier substrate including a network of electrical connections; a least one electronic chip having a back face fixed to a front mounting face of the carrier substrate; and an encapsulation cover of said chip, fixed at least above said mounting face of said carrier substrate in a position such that it extends above the chip; said encapsulation cover comprising a substrate made of a coating material at least partly overmolded around at least one electrically conductive insert; said insert having at least one electrical contact which is not covered by said coating material, this electrical contact being placed above an electrical connection pad of the mounting face of the carrier substrate or above an electrical connection pad of a front face of the chip, said electrical contact and said electrical connection pad being electrically connected.

Said cover may be fixed above said carrier substrate by way of an annular layer of adhesive, interposed between the carrier substrate and a rear peripheral zone of said overmolded substrate.

Said electrical contact and said electrical connection pad may be electrically linked by way of an electrically conductive material.

Said overmolded substrate may be provided with a peripheral rib surrounding said chip at a distance, the cover being fixed above said carrier substrate by way of a layer of adhesive interposed between said carrier substrate and said peripheral rib.

### BRIEF DESCRIPTION OF THE DRAWINGS

Electronic packages and modes of manufacturing encapsulation covers for electronic packages will now be described by way of non-limiting examples, which are illustrated by the appended drawings in which:

FIG. 1 shows a cross section of an electronic package;

FIG. 2 shows a cross section of a mold for manufacturing an encapsulation cover for the package of FIG. 1, in one manufacturing step;

FIG. 3 shows a horizontal cross section of the mold of FIG. 2;

FIG. 4 shows a cross section of the manufacturing mold of FIG. 2, in another step of manufacturing the encapsulation cover;

FIG. 5 shows a step of manufacturing the package of FIG. 1, in cross section;

FIG. 6 shows another step of manufacturing the package of FIG. 1, in cross section;

FIG. 7 shows a cross section of another electronic package;

FIG. 8 shows a cross section of a mold for manufacturing an encapsulation cover for the package of FIG. 7, in one manufacturing step;

FIG. 9 shows a horizontal cross section of the mold of FIG. 8, in another step of manufacturing the encapsulation cover;

FIG. 10 shows a step of manufacturing the package of FIG. 7, in cross section;

FIG. 11 shows another step of manufacturing the package of FIG. 7, in cross section;

FIG. 12 shows a cross section of another electronic package;

FIG. 13 shows a cross section of a mold for manufacturing an encapsulation cover for the package of FIG. 12, in one manufacturing step;

FIG. 14 shows a horizontal cross section of the mold of FIG. 13, in another step of manufacturing the encapsulation cover;

FIG. 15 shows a step of manufacturing the package of FIG. 12, in cross section;

FIG. 16 shows a cross section of another electronic package;

FIG. 17 shows a horizontal cross section of the electronic package in FIG. 16;

FIG. 18 shows a cross section of another electronic package; and

FIG. 19 shows a cross section of a mold for manufacturing an encapsulation cover for the package of FIG. 18, in one manufacturing step.

### DETAILED DESCRIPTION

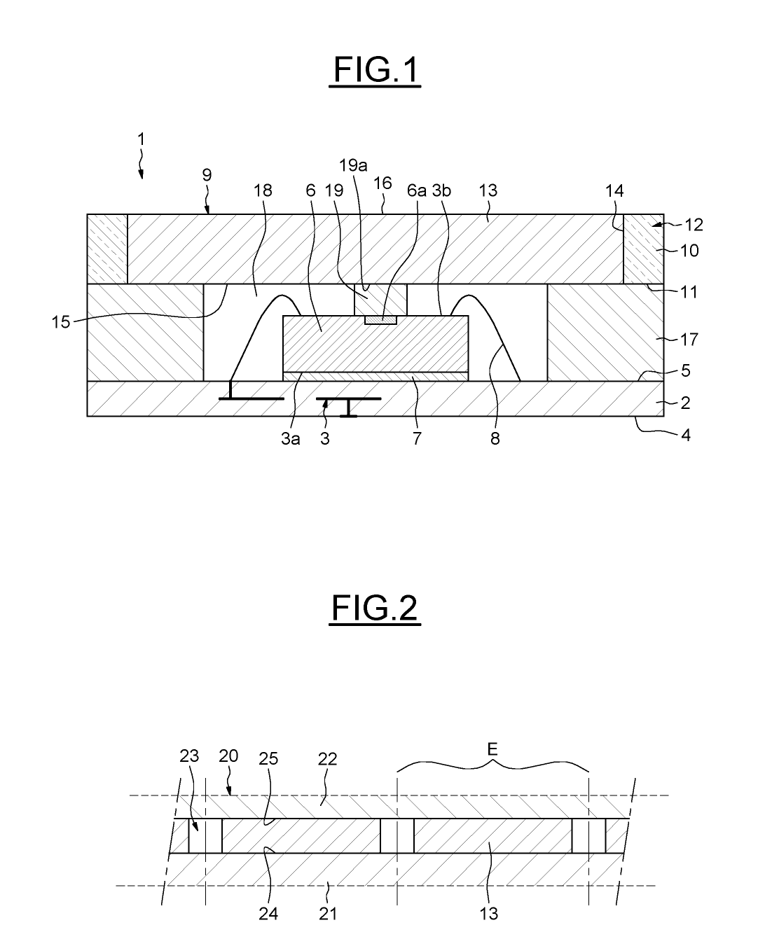

FIG. 1 illustrates an electronic package 1 which comprises a carrier substrate 2, made of a dielectric material, including an integrated network of electrical connections 3 and having a back face 4 and a front mounting face 5. The outline of the carrier substrate 2 is, for example, square or rectangular.

The package 1 comprises an electronic chip 6 mounted above the front face 5 of the carrier substrate 2 by way of a layer of adhesive 7 interposed between the front face 5 of the carrier substrate 2 and a back face 3a of the electronic chip 6.

The chip 6 is electrically connected to the network of electrical connections 2 by way of electrical connection wires 8 connecting pads of the front face 5 of the carrier substrate 2 and pads of the front face 3b of the chip 6, the back face 4 of the carrier substrate 2 being provided with electrical connection pads for the external electrical connections of the package 1.

The package 1 comprises an encapsulation cover 9 for the chip 6 and electrical connection wires 8 on the front of the carrier substrate 2, the encapsulation cover 9 being located above and at a distance from the chip 6, parallel to the carrier substrate 2, and having an outline corresponding to that of the carrier substrate 2. According to one variant embodiment, the chip 6 could be mounted on the carrier substrate 2 by way of electrical connection elements, such as balls, which electrically connect the chip 6 and the network of electrical connections 3.

The encapsulation cover 9 comprises a ring-shaped overmolded substrate 10 made of a coating material, for example a thermoset resin, which has a back mounting face 11 and a front face 12, which are opposite, flat and parallel, and comprises an insert 13 in the form of a plate and the periphery of which is integrated and held within a through-passage 14 of the overmolded substrate 10. The insert 13 extends in front of and at a distance from the chip 6 and has, for example, a square or rectangular outline. For example, the insert 13 has back and front faces 15 and 16, which are not covered by the overmolded substrate 10, and which extend substantially in the plane of the back and front faces 11 and 12 of the overmolded substrate 10.

The insert 13 is made of an electrically conductive material. The insert 13 is, for example, made of an electrically conductive metal, for example based on copper, aluminum or iron.

The encapsulation cover 9 is fixed above the carrier substrate 2 by way of a local ring-shaped connecting spacer 17 interposed between a peripheral zone of the front face 5 of the carrier substrate 2 and a peripheral zone of the back face of the encapsulation cover 9, the ring-shaped spacer 17 extending at a distance from the periphery of the chip 6 and the electrical connection wires 10. The spacer 17 may partially cover the back face 11 of the overmolded substrate 10 or cover the back face 11 of the overmolded substrate 10 and a peripheral portion of the back face 15 of the insert 13.

The thickness of the spacer 17 determines the gap between the cover 10 and the carrier substrate 2. The spacer 17 may comprise an adhesive including spacing balls which determine a minimum gap between the cover 10 and the carrier substrate 2.

Thus, the carrier substrate 2, the cover 9 provided with the insert 13 and the spacer 17 define a sealed chamber 18 in which the chip 6 is located.

A local spacer 19, placed at a distance from the electrical connection wires 8, is interposed between an electrical contact of the front face 3b of the chip 6 which is not covered by the coating material and a local zone 19a of the back face 15 of the insert 13 (which extends through the overmolded substrate 10).

The local spacer 19 is made of an electrically conductive material and may be made up of an electrically conductive adhesive or a solder. The local zone 19a and the local spacer 19 are located above an electrical connection pad 6a of the front face 3b of the chip 6, such that the insert 13 is connected to the electronic circuits of the chip 6. As an example, this pad 6a may be a ground pad for the electronic circuits of the chip 6, and in this configuration the insert 13 forms an electromagnetic protection screen between the chip 6 and the exterior. In another configuration, the pad 6a is a signal pad and in this variant embodiment, the insert 13 may take the form of an antenna.

Additionally, the local spacer 19 may be made of a heat-conducting material. Thus, the insert 13 included in the cover 9 may form a means for dissipating the heat generated by the chip 6 to the outside via the attached local spacer 19 which then forms a thermal seal.

The encapsulation cover 9 is the result of a wafer-scale manufacturing process which will now be described.

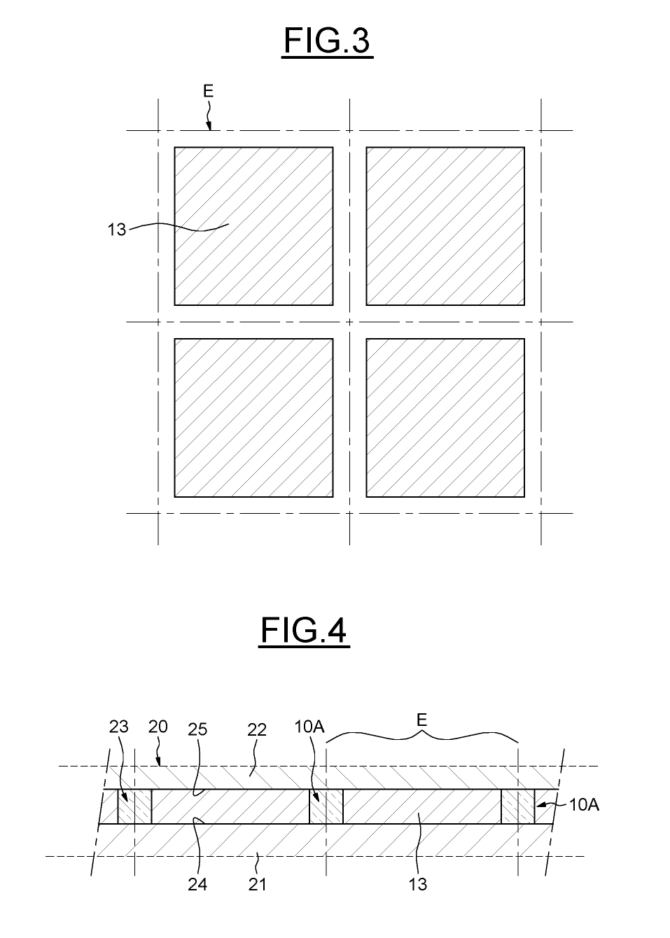

As illustrated in FIGS. 2 and 3, a mold 20 is obtained which comprises a lower part 21 and an upper part 22 between which a cavity 23 is formed. The parts 21 and 22 of the mold 20 have faces 24 and 25 which are opposite, flat and parallel, and which delimit the cavity 23 in the direction of the thickness of the covers 9 to be obtained. Optionally, these opposite faces 24 and 25 are covered with layers made of a compressible material.

A plurality of inserts 13 is also obtained, resulting for example from cutting a substrate along parallel rows and parallel columns.

With the mold 20 open, inserts 13 are placed on the face 24, at respective locations in the sites E corresponding to covers 9 to be obtained, these sites E being adjacent and arranged in a square or rectangular matrix.

Next, the mold 20 is closed by placing the upper part 22 above the lower part 21. In this position, the opposite faces 15 and 16 of the inserts 13 are facing the opposite faces 24 and 25 of the cavity 23 and are pressed against the aforementioned optional compressible layers. Free spaces separate the inserts 13, these spaces straddling the rows and columns separating the adjacent sites E.

Next, as illustrated in FIG. 4, a coating material, for example a thermosetting epoxy resin, is injected into the cavity 23 of the mold 20 and fills said free spaces, and this coating material is set.

After removal from the mold, a collective substrate 10A provided with inserts 13, and overmolded around these inserts 13, is obtained.

According to one variant embodiment, the collective substrate 10A is cut along the rows and columns delimiting the sites E in order to obtain covers 9.

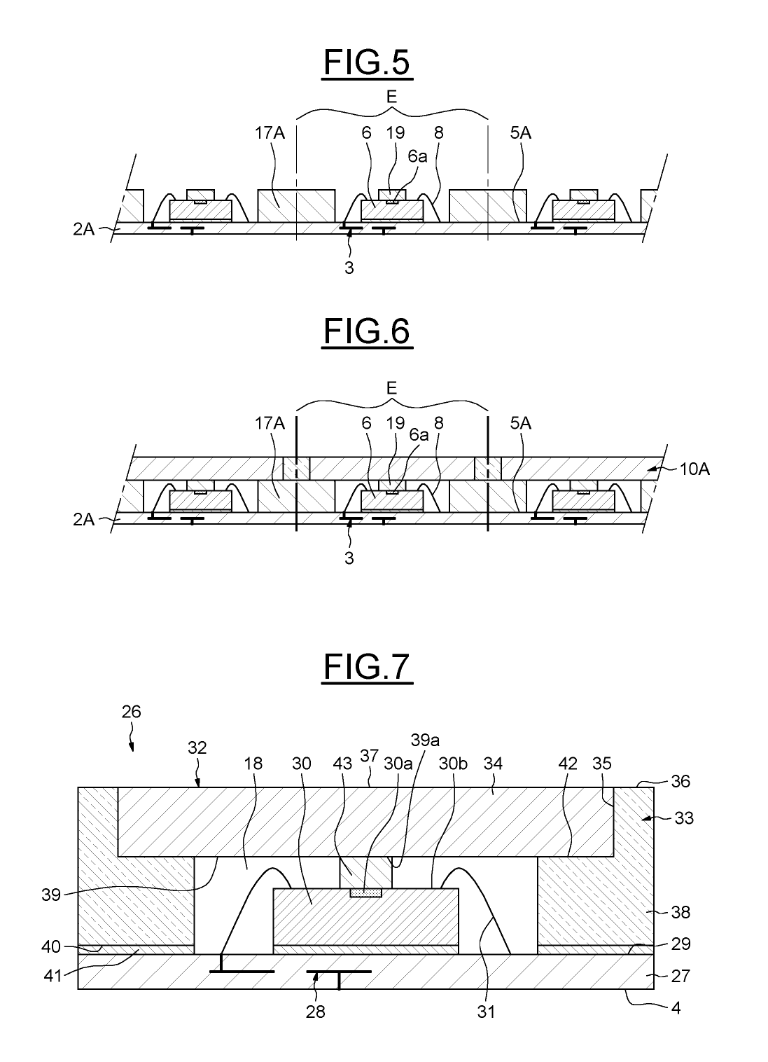

According to another variant embodiment, as illustrated in FIG. 5, a collective carrier substrate 2A is obtained which is provided, at sites E corresponding to electronic packages 1 to be obtained, with respective networks of electronic connections 3 and which is provided, on its front face 5A, with electronic chips 6 at respective locations at the sites E and with electrical connection wires 8, these sites E being adjacent and arranged in a square or rectangular matrix.

Next, collective beads 17A of adhesive are spread over the front face 5A of the collective carrier substrate 2A, along border zones between the sites E, surrounding the central zones of the sites E in which the chips 6 are located. Local blobs of conductive adhesive are deposited on the chips 6, corresponding to local spacers 19 to be obtained above the electrical connection pads 6a of the chips 6.

Next, the overmolded collective substrate 10A, provided with the inserts 13, is placed on top of the beads of adhesive 17A and the blobs of adhesive 19 and the adhesive is set so as to fix the collective substrate 10A above the collective carrier substrate 2A and the inserts 13 above the chips 6.

Next, the assembly formed is cut along rows and columns separating the sites E, perpendicularly to the collective substrates 2A and 10A and through the beads of adhesive 17A, between and at a distance from the inserts 13.

A plurality of electronic packages 1, produced at the sites E, is then obtained, in each one of which the carrier substrate 2 is a portion of the collective carrier substrate 2A, the cover 9 comprises an overmolded substrate 10 formed by a portion of the overmolded collective substrate 10A, including an insert 13, and the connecting spacer 17 is a portion of the collective beads of set adhesive 17A, the cover 9 resulting from the substrate 10 being overmolded around the insert 13, the chip 6 and the insert 13 being connected by the local spacer 19.

FIG. 7 illustrates an electronic package 26 which comprises a carrier substrate 27 including an integrated network of electrical connections 28 and provided, on a front mounting face 29, with an electronic chip 30, the chip 30 being connected to the network of electrical connections 28 by electrical connection wires 31.

The electronic package 26 comprises an encapsulation cover 32 which comprises a ring-shaped overmolded substrate 33 made of a coating material, and an insert 34 which takes the form of a plate located in front of the chip 30 and the periphery of which is integrated and held within a through-passage 35 of the overmolded substrate 33. The overmolded substrate 33 and the insert 34 have front faces 36 and 37 located in one and the same plane parallel to the carrier substrate 27.

The ring-shaped overmolded substrate 33 is provided, as one piece, with a ring-shaped rib 38 which protrudes with respect to a back face 39 of the insert 34 and which is located around and at a distance from the periphery of the chip 30 and the electrical connection wires 31.

The ring-shaped rib 38 has a back mounting face 40 which is fixed to the front face 29 of the carrier substrate 27 by way of a local ring-shaped strip of adhesive 41. In the example shown, the periphery of the back face 39 of the insert 34 is adjoined to a ring-shaped front face 42 of the ring-shaped rib 38, such that the corresponding part of the ring-shaped rib 38 forms a ring-shaped spacer between the carrier substrate 27 and the insert 34 of the cover 32.

In the same way as for the electronic package 1 described with reference to FIG. 1, a local spacer 43 made of an electrically conductive material is interposed between a front electrical connection pad 30a of the chip and a local zone 39a, forming an electrical contact which is not covered by the coating material, of the back face 39 of the insert 34 made of an electrically conductive material.

The encapsulation cover 32 is the result of a wafer-scale manufacturing process which will now be described.

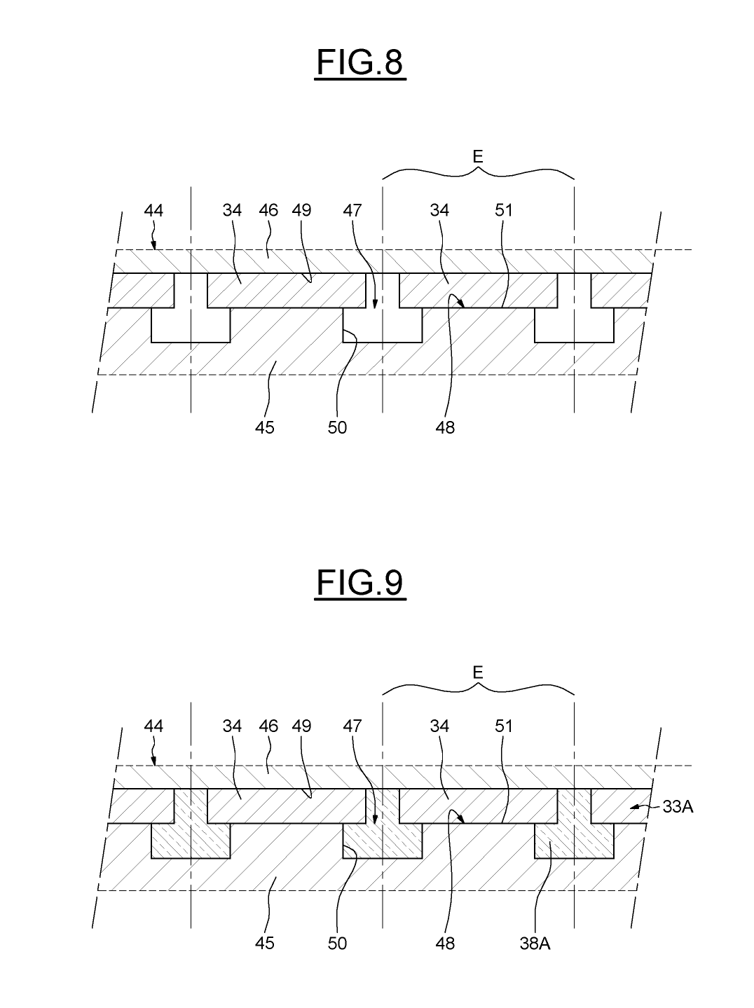

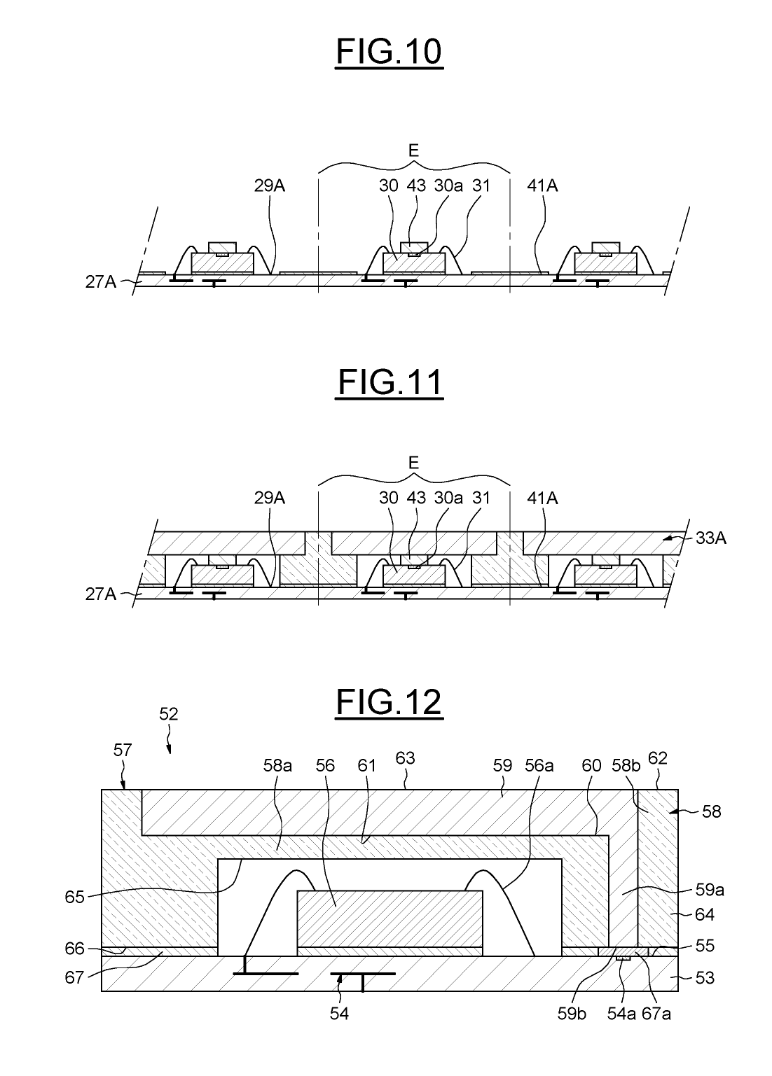

As illustrated in FIG. 8, a mold 44 is obtained which comprises a lower part 45 and an upper part 46 between which a cavity 47 is formed. The parts 45 and 46 of the mold 44 have opposite faces 48 and 49 which delimit the cavity 47 in the direction of the thickness of the covers 32 to be obtained.

The face 48 of the lower part 45 of the mold 44 has adjacent sites E in a matrix, corresponding to covers 32 to be obtained. The face 48 has cross-shaped grooves 50 which are formed along rows and columns of the matrix forming the sites E and which are of equal depth.

Thus, at each site E, the face 48 of the lower part 45 of the mold 44 comprises flat zones 51 which are circumscribed by corresponding portions of the grooves 50.

The face 49 of the upper part 46 of the mold 44 is flat and parallel to the zones 51 of the lower part 45 of the mold 44.

Optionally, the flat zones 51 of the lower part 45 of the mold 44 and the face 49 of the upper part 46 of the mold 44 are covered with layers made of a compressible material.

A plurality of inserts 34 is also obtained.

With the mold 44 open, inserts 34 are placed such that, when the mold is closed, the inserts 34 are interposed between the zones 51 of the lower part 15 and the face 49 of the upper part 46 of the mold 44, respectively, at the respective sites E corresponding to covers 32 to be obtained. In this position, the inserts are at a distance from one another and leave free spaces between them which communicate with the grooves 50, the grooves being partially covered such that in cross section, these free spaces and the grooves 50 form T-shapes.

Next, as illustrated in FIG. 9, an opaque coating material, for example a thermosetting epoxy resin, is injected into the cavity 47 of the mold 44 and this coating material is set.

After removal from the mold, a collective substrate 33A is obtained which is provided with a plurality of cross-shaped grooves 38A at the locations of the grooves 50 and provided with inserts 30, which inserts are integrated and held within the coating material forming the collective substrate 33A, the latter being overmolded around the inserts 30.

According to one variant embodiment, the collective substrate 33A is cut along the rows and columns delimiting the sites E in order to obtain covers 32.

According to another variant embodiment, as illustrated in FIG. 11, a collective carrier substrate 27A is obtained which is provided, at sites E corresponding to electronic packages 26 to be obtained, with respective networks of electronic connections 28 and which is provided, on its front face 29A, with electronic chips 30 at respective adjacent sites E and with electrical wires 31.

Next, collective strips 41A of adhesive are spread over the front face 29A of the collective carrier substrate 27A, straddling the rows and columns separating the sites E with a view to forming the strips 41 of adhesive of the packages 26 to be obtained. Local blobs of conductive adhesive are deposited on the chips 30, corresponding to local spacers 43 to be obtained above the electrical connection pads 30a of the chips 30.

Next, the overmolded collective substrate 33A, provided with ribs 38A and with inserts 34, is placed so that the ribs 38A are on top of the collective strips 41A of adhesive and the inserts 34 are on top of the adhesive spacers 43, and the adhesive is set so as to fix the collective substrate 33A above the collective carrier substrate 27A and the inserts 34 on top of the spacers 43.

Next, the assembly formed is cut along rows and columns separating the sites E, perpendicularly to the collective carrier substrate 27A and through the overmolded collective substrate 33A and the collective ribs 41A, between and at a distance from the inserts 30.

A plurality of electronic packages 26, produced at the sites E, is then obtained.

FIG. 12 illustrates an electronic package 52 which comprises a carrier substrate 53 including an integrated network of electrical connections 54 and provided, on a front mounting face 55, with an electronic chip 56, the chip 56 being connected to the network of electrical connections 54 by electrical connection wires 56a.

The electronic package 52 comprises an encapsulation cover 57 which comprises an overmolded solid substrate 58, made of a coating material, which extends in front of and at a distance from the chip 56 and the electrical connection wires 56a, and an insert 59 which takes the form of a plate which is inserted into a front space 60 of the overmolded substrate 58, such that the overmolded substrate 58 has a part 58a which covers a back face 61 of the insert 59 and a part 58b which surrounds the periphery of the insert 59. The overmolded substrate 58 and the insert 59 have front faces 62 and 63 located in one and the same plane parallel to the carrier substrate 53. In this arrangement, the insert 59 does not pass through the overmolded substrate 58.

In the same way as for the electronic package 26, the overmolded substrate 58 is provided, as one piece, with a ring-shaped rib 64 which protrudes with respect to a back face 65 of the overmolded substrate 58 and which is located around and at a distance from the periphery of the chip 56 and the electrical connection wires 56a.

The ring-shaped rib 64 has a back mounting face 66 which is fixed to the front face 55 of the carrier substrate 53 by way of a local ring-shaped strip of adhesive 67.

The insert 59 additionally comprises, for example as one piece, an electrical connection portion 59a which extends from its back face 61, through the rear protruding rib 64 of the overmolded substrate 58 and up to the back mounting face 66 of this rear protruding rib 64 such that the back face 59b, forming an electrical contact which is not covered by the coating material, of the electrical connection portion 59a is located above an electrical connection pad 54a of the electrical connection network 54, which pad is formed on the front mounting face 55 of the carrier substrate 53.

According to one variant embodiment, the ring-shaped strip of adhesive 67 is made of an electrically conductive material, such that the electrical connection portion 59a, and consequently the insert 59 as a whole, are connected to the electrical connection pad 54a via this strip of adhesive 67.

According to another variant embodiment illustrated in FIG. 12, a dot 67a made of an electrically conductive material, for example a dot of adhesive or a solder included within a ring-shaped strip of non-electrically conductive adhesive 67, is interposed between the back face of the electrical connection leg 59a and the electrical connection pad 54a.

The encapsulation cover 57 is the result of a wafer-scale manufacturing process which will now be described.

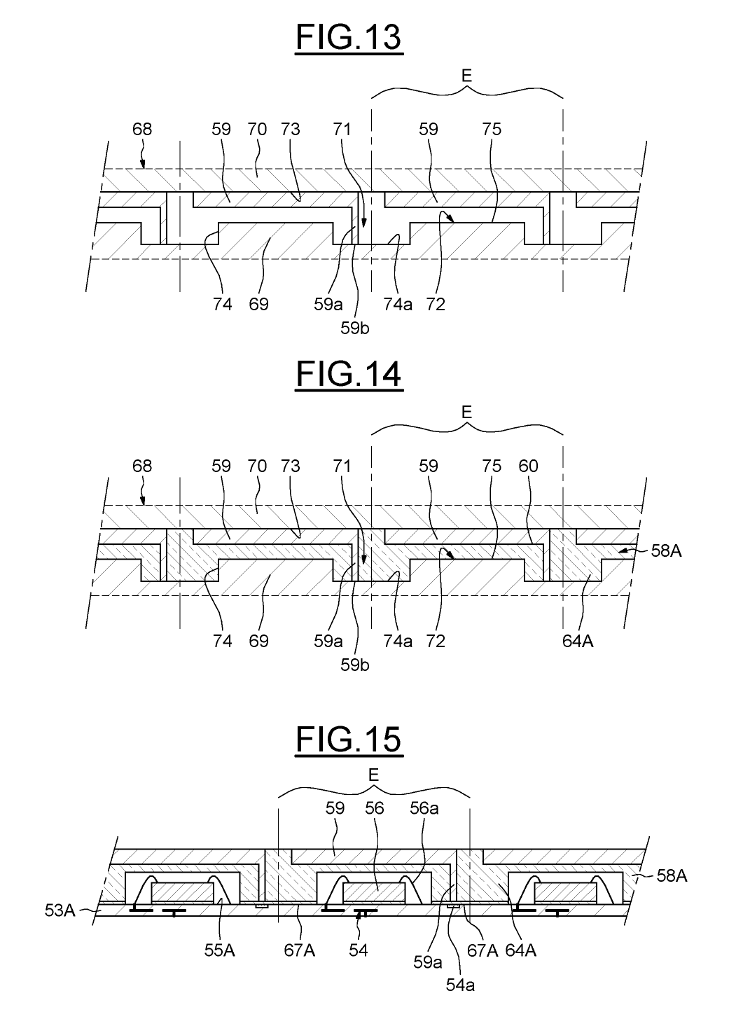

As illustrated in FIG. 13, a mold 68 is obtained which comprises two parts 69 and 70 between which a cavity 71 is formed. The parts 69 and 70 of the mold 68 have opposite faces 72 and 73 which delimit the cavity 71 in the direction of the thickness of the covers 57 to be obtained.

The face 72 of the part 69 of the mold 68 has adjacent sites E in a matrix, corresponding to covers 57 to be obtained. The face 72 has cross-shaped grooves 74 which are formed along rows and columns of the matrix forming the sites E and which are of equal depth.

Thus, at each site E, the face 72 of the part 69 of the mold 68 comprises flat zones 75 which are circumscribed by corresponding portions of the grooves 74.

The face 73 of the part 70 of the mold 68 is flat and parallel to the zones 75 of the part 69 of the mold 68.

A plurality of inserts 59 is also obtained.

With the mold 68 open, inserts 59 are placed such that, when the mold is closed, the front faces 63 of the inserts 59 are adjoined to the face 73 of the part 70 of the mold 68 and the back faces 61 of the inserts 59 are at a distance from the zones 75 of the part 70 of the mold 68, at the respective sites E corresponding to covers 57 to be obtained. In this position, the inserts 59 are at a distance from one another and leave free spaces between them which communicate with the grooves 74 and and leave free spaces between the back faces 61 of the inserts 59 and the zones 75 of the face 72 of the part 69 of the mold 68.

In addition, the electrical connection portions 59a of the inserts 59 are fitted into the grooves 74, such that their back faces 59b make contact with the bottoms 74a of the grooves 74. A compressible material, on which the electrical connection legs 59a bear, may cover the bottoms 74a of the grooves 74.

Next, as illustrated in FIG. 14, an opaque coating material, for example a thermosetting epoxy resin, is injected into the cavity 71 of the mold 68 and this coating material is set.

After removal from the mold, a collective substrate 58A is obtained which is provided with a plurality of cross-shaped ribs 64A at the locations of the grooves 74 and provided with inserts 59 bearing legs 59a, which inserts are integrated and held within the coating material forming the collective substrate 58A provided with ribs 64a, the ends of the legs 59a being uncovered.

According to one variant embodiment, the collective substrate 58A is cut along the rows and columns delimiting the sites E in order to obtain covers 57.

According to another variant embodiment, as illustrated in FIG. 15, a collective carrier substrate 53A is obtained which is provided, at sites E corresponding to electronic packages 52 to be obtained, with respective networks of electronic connections 54 and which is provided, on its front face 55A, with electronic chips 56 at respective adjacent sites E and with electrical wires 57.

Collective strips 67A of adhesive are spread over the front face 55A of the collective carrier substrate 53A, straddling the rows and columns separating the sites E with a view to forming the strips 67 of adhesive of the packages 52 to be obtained, potentially while inserting the electrical connection points 67a therein.

Next, the overmolded collective substrate 58A, provided with ribs 64A and with inserts 59, is placed so that the ribs 64A are on top of the collective strips 67A of adhesive, and the adhesive is set so as to fix the collective substrate 58A above the collective carrier substrate 53A.

Next, the assembly formed is cut along rows and columns separating the sites E, perpendicularly to the collective carrier substrate 53A and through the overmolded collective substrate 58A and the collective ribs 64A, between and at a distance from the inserts 59.

A plurality of electronic packages 52, produced at the sites E, is then obtained.

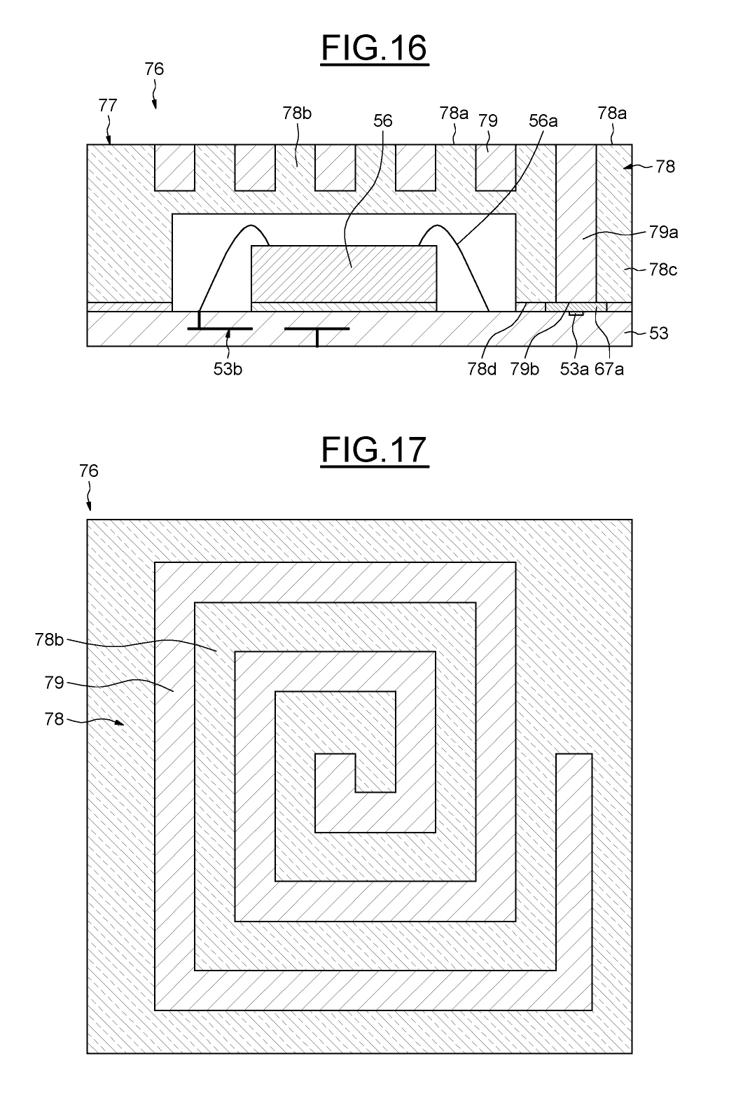

FIGS. 16 and 17 illustrate an electronic package 76 which differs from the electronic package 52 described with reference to FIG. 12 solely in that it comprises an encapsulation cover 77 the overmolded substrate 78 of which is provided with an insert 79 in the place of the insert 59 and which takes the form of a wire element, for example wound in a spiral, made of an electrically conductive material, the turns of which are adjacent to the front outer face 78a of the overmolded substrate 78. This time, the overmolded substrate 78 comprises parts 78b included between the turns of the insert 79. The wire insert 59 may be circular, rectangular or square in cross section.

An outer end of the spiral-shaped insert 59 is extended by a connection portion 79a, equivalents to the connection leg 59a, which extends perpendicularly to the carrier substrate 53 and which passes through the ring-shaped rib 78c of the overmolded substrate 78. The back face 79b, forming an electrical contact which is not covered by the coating material, of the connection portion 79a, located on a back mounting face 78d of the rib 78c, is connected to a front pad 53a of the electrical connection network 53b of the carrier substrate 53 in the same way as for the example described with reference to FIG. 12.

The spiral-shaped insert 79 may form an antenna for receiving and/or transmitting signals arising, for example, from the chip 56, via the network of electrical connections of the carrier substrate. The insert 79 could take any suitable shape capable of forming an antenna or any other electronic component.

The encapsulation cover 77 and the electronic package 76 may be manufactured in the same way as that which has been described above with reference to FIGS. 13 to 15.

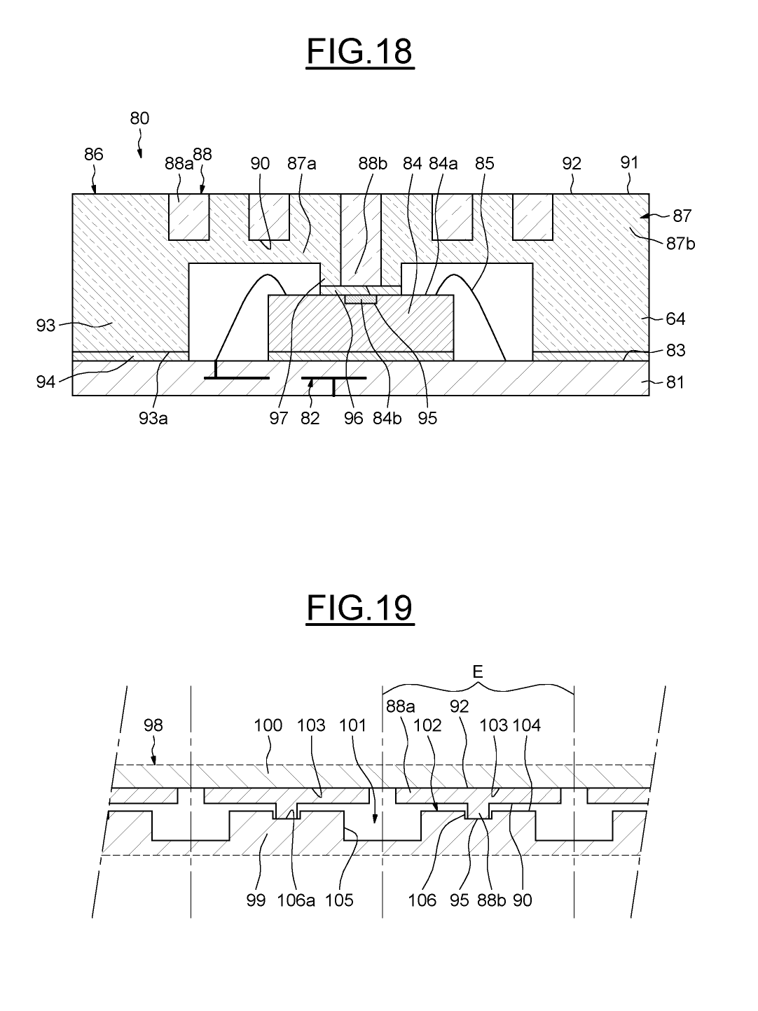

FIG. 18 illustrates an electronic package 80 which comprises a carrier substrate 81 including an integrated network of electrical connections 82 and provided, on a front mounting face 83, with an electronic chip 84, the chip 84 being connected to the network of electrical connections 82 by electrical connection wires 85.

The electronic package 80 comprises an encapsulation cover 86 which comprises an overmolded solid substrate 87, made of a coating material, which extends in front of and at a distance from the chip 84 and the electrical connection wires 85, and an insert 88 made of an electrically conductive material.

The insert 88 takes the form of a wire element 88a, for example wound in a spiral, in the same way as the insert 79 described with reference to FIGS. 16 and 17. The overmolded substrate 87 and the turns of the insert 88 have front faces 91 and 92 located in one and the same plane parallel to the carrier substrate 81, such that the front face 92 of the insert 88 is uncovered.

The overmolded substrate 87 has a part 87a which covers a back face 90 of the spiral-shaped wire 88a of the insert 88 and which extends forwards between the turns of the spiral-shaped wire 88a and a part 87b which surrounds the periphery of the spiral-shaped wire 88a of the insert 88.

In the same way as for the electronic package 52 described with reference to FIG. 12, the overmolded substrate 87 is provided with a ring-shaped rib 93 which protrudes backwards, the back mounting face 93a of which is fixed to the front face 83 of the carrier substrate 81 by way of a ring-shaped layer of adhesive 94.

In this exemplary embodiment, an inner end of the spiral-shaped wire 88a of the insert 88 is extended by a rear portion 88b which protrudes backwards with respect to its back face 90, which forms a spacer. This rear portion 88b passes through the part 87b of the overmolded substrate 87.

The rear portion 88b of the insert 88 has a back face 95, which forms an electrical contact which is not covered by the coating material and which is located above an electrical connection pad 84b formed on or in the central part of the front face 84a of the chip 84 and which is connected to this electrical connection pad 84b made on or in the front face 84a of the chip 84b by way of a local layer 96 of an electrically conductive material.

In addition, the part 87a of the overmolded substrate 87 is provided with a portion 97 which protrudes backwards and which surrounds the rear portion 88b of the insert 88 so that the back face 95 is uncovered.

The spiral-shaped insert 88 may form an antenna for receiving and/or transmitting signals arising directly from the chip 84. The insert 88 could take any suitable shape capable of forming an antenna or any other electronic component.

The encapsulation cover 86 is the result of a wafer-scale manufacturing process, as follows.

To this end, as illustrated in FIG. 19, a mold 98 comprises two parts 99 and 100 forming between them a cavity 101 and having opposite faces 102 and 103. The face 102 of the part 99 has, at sites E, zones 104 separated by cross-shaped grooves 105 straddling the rows and columns separating the sites E.

This time, spaces 106 are made in the zones 104 of the part 99 of the mold 98. Inserts 88 are placed between the parts 99 and 100 of the mold 98, in following positions. The front faces 92 of the inserts 88 bear against the flat face 103 of the part 100 of the mold 98. The back faces 95 of the protruding rear portions 88b of the inserts 88 bear against the bottoms 106a of the spaces 106 of the part 99 of the mold 88. Spaces are left free between the back faces 90 of the inserts 88 around the protruding rear portions 88b and the zones 104 of the face 102 of the part 99 of the mold 98 around the spaces 106. Free spaces are left between the periphery of the protruding rear portions 88b of the inserts 88 and the periphery of the spaces 106.

The following steps of the wafer-scale manufacturing of the encapsulation cover 98 are equivalent to those described above.

However, when assembling a collective overmolded substrate including a plurality of encapsulation covers 98, which substrate is equivalent to the collective overmolded substrate 58A, local layers of electrically conductive adhesive 95 should be deposited on the front faces 84a of the chips 84, which are mounted on a collective carrier substrate, in order to connect the back faces 95 of the protruding portions 88b of the inserts 88 and the front electrical connection pads 84b of the chips 84.

According to other exemplary embodiments, electronic packages (not shown) comprise encapsulation covers comprising overmolded substrates including adapted inserts resulting from specific combinations of the inserts described with reference to FIGS. 1, 7, 16 and 18, the modes of manufacturing and mounting of such encapsulation covers resulting from specific combinations of the modes of manufacturing and mounting described above.

According to one variant embodiment, an adapted insert electrically connects an electronic chip and a network of electrical connections of a carrier substrate. To achieve this, this specific insert comprises rear electrical connection portions having back faces which are connected to an electrical connection pad of an electronic chip and an electrical connection pad of a network of electrical connections of a carrier substrate, respectively.

According to another variant embodiment, an adapted insert has rear electrical connection portions which are connected to front pads of a network of electrical connections of a carrier substrate.

According to another variant embodiment, an adapted insert has rear electrical connection portions which are connected to pads of an electronic chip.

According to another variant embodiment, an adapted insert is completely embedded within the overmolded substrate, with the exception of one or more rear electrical contact surfaces.

1. A method for manufacturing, comprising the following steps:
placing at least one insert made of an electrically conductive material and including at least one electrical contact surface inside a cavity of a mold in a position such that said electrical contact surface makes contact with a face of said cavity of the mold;
injecting a coating material into said cavity; and
setting the coating material in order to obtain a substrate that is at least partly overmolded around said insert, so as to produce at least one cover comprising at least a portion of said overmolded substrate and the at least one insert wherein at least part of said electrical contact surface is not covered by the coating material.

2. The method according to claim 1, further comprising cutting through said overmolded substrate at a distance from said electrical insert.

3. The method according to claim 1, wherein said electrical contact surface of said insert is located on a side of a mounting face of said cover.

4. The method according to claim 1, wherein said insert comprises a substrate.

5. The method according to claim 1, wherein said insert comprises a wire element.

6. The method according to claim 1, further comprising positioning the insert within the mold adjacent a layer made of a compressible material that at least partly forms the face of said cavity with which said electrical contact surface makes contact.

7. The method according to claim 1, wherein said insert has a part that makes contact with a face of the mold opposite said face with which said electrical contact makes contact.

8. The method according claim 1, wherein said opposite faces of the cavity of the mold are parallel.

9. The method according to claim 1, wherein a face of the cavity of the mold comprises at least one zone surrounded by at least one protruding groove, said injected coating material filling said at least one protruding groove to produce said overmolded substrate with at least one protruding rib corresponding to said at least one protruding groove.

10. The method according to claim 9, wherein said electrical contact surface of said electrical insert makes contact with said at least one zone.

11. The method according to claim 9, wherein said electrical contact surface of said electrical insert makes contact with a bottom surface of said at least one protruding groove.

12. The method according claim 9, further comprising cutting through said overmolded substrate and through said protruding rib.

13. The method according to claim 1, further comprising:
obtaining a carrier substrate provided with an electronic chip on top of a mounting face; and
mounting the encapsulation cover above said mounting face of said carrier substrate, such that the encapsulation cover extends above said electronic chip, said electrical contact surface of said insert located above and electrically connected to an electrical connection pad of said carrier substrate.

14. The method according to claim 13, comprising the following step: electrically connecting said electrical contact surface of said insert and said electrical connection pad by interposing an electrically conductive material therebetween.

15. The method according to claim 1, further comprising:
obtaining a carrier substrate provided with an electronic chip on top of a mounting face; and
mounting the encapsulation cover above said mounting face of said carrier substrate, such that the encapsulation cover extends above said electronic chip, said electrical contact surface of said insert located above and electrically connected to an electrical connection pad of said chip.

16. The method according to claim 15, comprising the following step: electrically connecting said electrical contact surface of said insert and said electrical connection pad by interposing an electrically conductive material therebetween.

17. An electronic package, comprising:
a carrier substrate including a network of electrical connections;
a least one electronic chip having a back face fixed to a front mounting face of the carrier substrate; and
an encapsulation cover over said electronic chip, fixed at least above said mounting face of said carrier substrate in a position such that it extends above the electronic chip, wherein said encapsulation cover comprises:
a substrate made of a coating material at least partly overmolded around at least one electrically conductive insert, wherein said electrically conductive insert comprises at least one electrical contact surface which is not covered by said coating material, said electrical contact positioned above and electrically connected to an electrical connection pad of a front face of the electronic chip.

18. The package according to claim 17, wherein said encapsulation cover is fixed above said carrier substrate by way of an annular layer of adhesive, interposed between the carrier substrate and a rear peripheral zone of said overmolded substrate.

19. The package according to claim 17, wherein said electrical contact surface and said electrical connection pad are electrically linked by way of an electrically conductive material.

20. The package according to claim 17, wherein said overmolded substrate includes a peripheral rib surrounding said electronic chip at a distance, the cover being fixed above said carrier substrate by way of a layer of adhesive interposed between said carrier substrate and said peripheral rib.

21. An electronic package, comprising:
a carrier substrate including a network of electrical connections;
a least one electronic chip having a back face fixed to a front mounting face of the carrier substrate; and
an encapsulation cover over said electronic chip, fixed at least above said mounting face of said carrier substrate in a position such that it extends above the electronic chip, wherein said encapsulation cover comprises:
a substrate made of a coating material at least partly overmolded around at least one electrically conductive insert, wherein said electrically conductive insert comprises at least one electrical contact surface which is not covered by said coating material, said electrical contact positioned above and electrically connected to an electrical connection pad of the mounting face of the carrier substrate.

22. The package according to claim 21, wherein said encapsulation cover is fixed above said carrier substrate by way of an annular layer of adhesive, interposed between the carrier substrate and a rear peripheral zone of said overmolded substrate.

23. The package according to claim 21, wherein said electrical contact surface and said electrical connection pad are electrically linked by way of an electrically conductive material.

24. The package according to claim 21, wherein said overmolded substrate includes a peripheral rib surrounding said electronic chip at a distance, the cover being fixed above said carrier substrate by way of a layer of adhesive interposed between said carrier substrate and said peripheral rib.
